(19) United States
(12) Patent Application Publication
(10) Pub. No.: US 2006/0270202 A1
(43) Pub. Date: Nov. 30, 2006

(54) TECHNIQUE FOR REDUCING SILICIDE NON-UNIFORMITIES BY ADAPTING A VERTICAL DOPANT PROFILE

(76) Inventors: Frank Wirbeleit, Dresden (DE); David Brown, Pleasant Valley, NY (US); Patrick Press, Dresden (DE)

Correspondence Address: WILLIAMS, MORGAN & AMERSON, 10333 RICHMOND, SUITE 1100, HOUSTON, TX, 77042, US

(21) Appl. No.: 11/379,079

(22) Filed: Apr. 18, 2006

(30) Foreign Application Priority Data
May 31, 2005 (DE) 10 2005 024 911.6

(51) Int. Cl. H01L 21/04

(52) U.S. Cl. 438/510

(57) ABSTRACT

By modifying the vertical dopant concentration in deep drain and source regions, the reaction behavior during the formation of metal silicide regions may be controlled. For this purpose, an increased dopant concentration is formed around a target depth for the metal silicide interface, thereby reducing the reaction speeds and thus improving the uniformity of the resulting metal silicide interface.

### BACKGROUND OF THE INVENTION

1. Field of the Invention

Generally, the present invention relates to the field of fabrication of integrated circuits, and, more particularly, to semiconductor devices having metal-silicide portions on semiconductor regions to reduce the resistance of the semiconductor regions.

2. Description of the Related Art

In modern ultra-high density integrated circuits, device features are steadily decreasing to enhance device performance and functionality. Shrinking the feature sizes, however, entails certain problems that may partially offset the advantages obtained by the reduced feature sizes. Generally, reducing the feature sizes of, for example, a transistor element may lead to a decreased channel resistance in the transistor element and thus result in a higher drive current capability and enhanced switching speed of the transistor. In decreasing the features sizes of these transistor elements, however, the increasing electrical resistance of conductive lines and contact regions, i.e., of regions that connect transistor areas, such as drain and source regions, with the periphery of the transistor element, becomes a dominant issue since the cross-sectional area of these lines and regions decreases with decreasing feature sizes. The cross-sectional area, however, determines in combination with the characteristics of the material comprising the conductive lines and contact regions the resistance of the respective line or contact region.

The above problems may be exemplified for a typical critical feature size in this respect, also referred to as a critical dimension (CD), such as the extension of the channel of a field effect transistor that forms below a gate electrode between a source region and a drain region of the transistor. Reducing this extension of the channel, commonly referred to as channel length, may significantly improve device performance with respect to fall and rise times of the transistor element due to the smaller capacitance between the gate electrode and the channel and due to the decreased resistance of the shorter channel. Shrinking of the channel length, however, also entails the reduction in size of any conductive lines, such as the gate electrode of the field effect transistor, which is commonly formed of polysilicon, and the contact regions that allow electrical contact to the drain and source regions of the transistor, so that consequently the available cross-section for charge carrier transportation is reduced. As a result, the conductive lines and contact regions exhibit a higher resistance unless the reduced cross-section is compensated for by improving the electrical characteristics of the material forming the lines and contact regions, such as the gate electrode, and the drain and source contact regions.

It is thus of particular importance to improve the characteristics of conductive regions that are substantially comprised of semiconductor material such as silicon. For instance, in modern integrated circuits, the individual semiconductor devices, such as field effect transistors, capacitors and the like, are primarily based on silicon, wherein the individual devices are connected by silicon lines and metal lines. While the resistivity of the metal lines may be improved by replacing the commonly used aluminum with, for example, copper and copper alloys, process engineers are confronted with a challenging task when an improvement in the electrical characteristics of silicon-containing semiconductor lines and semiconductor contact regions is required.

With reference to FIGS. 1a and 1b, an exemplary process for manufacturing an integrated circuit containing, for example, a plurality of MOS transistors, will now be described in order to illustrate the problems involved in improving the electrical characteristics of silicon-containing semiconductor regions in more detail.

In FIG. 1a, a semiconductor structure 100 includes a substrate 101, for example, a silicon substrate in which is formed a field effect transistor 110 of a specified conductivity type, such as an N-channel transistor or a P-channel transistor. The transistor element 110 comprises an isolation structure 113 formed of an insulating material, such as silicon dioxide, silicon nitride and the like, which defines an active region 112 in the substrate 101. A gate electrode 115 is formed over a gate insulation layer 118 that separates the gate electrode 115 from the active region 112. Spacer elements 116 made of, for example, silicon dioxide or silicon nitride, are located at the sidewalls of the gate electrode 115. In the active region 112, source and drain regions 114 including respective extensions 114a are formed and exhibit an appropriate lateral dopant profile required to connect to a channel region 111, in which a conductive channel builds up between the drain and the source regions 114 upon application of an appropriate control voltage on the gate electrode 115.

As previously discussed, the gate length of the transistor element 110, indicated as 1151, determines the channel length of the transistor 110 and therefore, as previously pointed out, significantly affects the electrical characteristics of the transistor element 110, wherein a reduced gate length and thus reduced overall dimensions of the transistor 110 will result in an increased resistance of the gate electrode 115 and contact areas 114b of the drain and source regions 114, although heavily doped, owing to the reduced area that is available for charge carrier transport.

A typical process flow for forming the semiconductor structure 100 may comprise the following steps. After the formation of the isolation structure 113 by well-known photolithographic etch and deposition techniques, implantation steps are performed to create a required vertical dopant profile in the active region 112. Subsequently, the gate insulation layer 118 is formed according to design requirements. Thereafter, the gate electrode 115 is formed by patterning, for instance, a polysilicon layer, by means of sophisticated photolithography and etching techniques. Then, a further implantation step for forming the source and drain extensions 114a within the source and drain regions 114 is performed and the spacer elements 116 may be formed by deposition and anisotropic etching techniques. The spacer element 116 may be used as an implantation mask for a subsequent implantation process in which a dopant is implanted into the active region 112 to form the source and drain regions 114, thereby creating the required high dopant concentrations in these regions.

It is to be noted that the dopant concentration varies in FIG. 1a in the horizontal direction, i.e., in the length direction of the gate electrode 115, as well as in the vertical direction, which will hereinafter be referred to as depth direction x, indicated by the arrow. Although the dopant profile of the source and drain regions 114 is depicted as a region having a sharp boundary, in reality the dopant profile varies continuously due to the moderately non-localized nature of the implantation process in the depth direction x and the subsequent annealing steps that are performed for activating the implanted atoms and for curing the crystalline damage caused by the implantation step. Usually, the dopant profile has to be selected in conformity with certain parameters of the transistor element 110. For example, a short gate length, and thus a short channel length, typically requires a “shallow” dopant profile in order to reduce the so-called “short channel effect.” Accordingly, the peak concentration in the depth direction x may be located near the surface, i.e., the contact area 114b, and may significantly drop with increasing depth.

FIG. 1b schematically shows the vertical dopant profile in the drain and source regions 114 as it may typically be encountered in conventional transistor elements having a gate length 1151 of approximately 100 nm and even less. In FIG. 1b, the horizontal axis represents the extension along the depth direction x, wherein for instance in FIG. 1a a specified depth xₛ is illustrated as a dashed line. The vertical axis represents the dopant concentration in a logarithmic scale, wherein the type of dopants in the drain and source regions 114 is determined by the type of transistor element that the transistor 100 represents. Thus, as is evident from FIG. 1b, a very high dopant concentration may be present at or near the surface 114b, which may significantly drop with increasing depth so as to yield a concentration at the specified depth xₛ that may be significantly less.

As previously pointed out, although a very high dopant concentration prevails at the contact area 114b and also within the gate electrode 115, in sophisticated applications, it is nevertheless common practice to further reduce the sheet resistance of these areas by forming a metal silicide within the source and drain regions 114 and the gate electrode 115.

FIG. 1c schematically shows the semiconductor structure 100 in a further advanced manufacturing stage. Here, metal silicide regions 117 are formed within the drain and source regions 114 and a metal silicide region 119 is formed in the gate electrode 115. Typically, the metal silicide regions 117, 119 are formed from a refractory metal, such as cobalt, nickel, titanium, platinum and the like, or combinations of two or more appropriate metals. For manufacturing the metal silicide regions 117, 119, typically one or more metal layers of specified thickness are conformally deposited by any appropriate deposition technique, such as physical vapor deposition, chemical vapor deposition and the like, wherein for instance an initial layer thickness may be selected to obtain a vertical extension of the silicide regions 117 in accordance with device requirements. Although a high content of metal silicide in the gate electrode 115 may be considered desirable so as to significantly reduce the resistance of the gate electrode 115, a thickness of the region 119 is, however, coupled to a specified thickness of the silicide regions 117, since frequently the regions 117 and 119 are formed in a common manufacturing process.

In other approaches, a more complex manufacturing scheme may be used to substantially decouple the formation of the regions 117, 119. It may now be assumed that a design thickness of the metal silicide region 117 is given by the depth xₛ. Based on the target depth xₛ and on the basis of the well-known reaction behavior of the refractory metal or metals under consideration with the underlying silicon, in principle the finally obtained thickness of the metal silicide regions 117 may be adjusted by correspondingly controlling process parameters, such as the initial layer thickness, temperature and duration of a subsequent heating process so as to initiate the diffusion of the refractory metal or metals into the silicon, thereby generating the metal silicide compound.

In practice, the metal silicide regions 117 may have, however, a certain roughness, indicated as 117a, the characteristics of which may significantly depend on device and process specifics. For instance, in some process regimes, P-channel transistors having a structure similar to the transistor 110 may exhibit a more pronounced roughness 117a for a nickel silicide compared to N-channel transistors formed within the same semiconductor structure 100. On the other hand, for nickel platinum silicide, the roughness 117a may be more pronounced for N-channel transistors compared to P-channel transistors. Owing to the non-uniformity of the metal silicide regions 117, i.e., the roughness 117a, which may also vary between different transistor types in the same structure, a degradation of electrical parameters of the semiconductor structure 100 may be observed due to pronounced parameter variation between different devices and due to, for instance, increased leakage currents at the drain and source regions 114. Moreover, with the continuous drive for scaling semiconductor devices, non-uniformities of the metal silicide regions 117 may negatively affect the performance of future device generations having even more tightly set process tolerances.

In view of the situation described above, there exists a need for an enhanced technique that avoids or at least reduces the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present invention is directed to a technique that enables the formation of metal silicide regions in highly doped semiconductor regions containing silicon, wherein the roughness of the metal silicide region may significantly be reduced to provide a more precisely defined interface with the surrounding semiconductor region. For this purpose, a vertical dopant concentration within the silicon-containing semiconductor region may be modified to provide, compared to conventional source and drain regions, an increased dopant concentration at or near a depth at which the interface of the metal silicide region is to be formed. The increased dopant concentration may significantly modify the diffusivity of the metal during the formation of the metal silicide region.

According to one illustrative embodiment of the present invention, a method comprises identifying a target depth of a metal silicide region to be formed in a silicon-containing semiconductor region which is formed above the substrate. The method further comprises forming a dopant profile in the silicon-containing semiconductor region along a depth direction of the silicon-containing semiconductor region on the basis of the target depth to obtain a local maximum of a dopant concentration in the neighborhood of the target depth. Finally, the metal silicide region is formed on the basis of the target depth.

According to another illustrative embodiment of the present invention, a method comprises identifying a first target depth for a metal silicide region for a drain and source region of a first specified transistor type that is to be formed on one or more substrates. The method further comprises forming the drain and source regions of the first specified transistor type on one or more substrates with a dopant profile on the basis of the first target depth, wherein the dopant profile is adjusted with respect to a depth direction of the one or more substrates, so as to obtain, for increasing depth, an increasing dopant concentration when approaching the first target depth. Finally, the metal silicide region is formed in the drain and source regions of the first specified transistor type on the basis of the first target depth.

### BRIEF DESCRIPTION OF THE DRAWINGS

The invention may be understood by reference to the following description taken in conjunction with the accompanying drawings, in which like reference numerals identify like elements, and in which:

FIG. 1a schematically shows a cross-sectional view of a conventional transistor prior to the formation of a metal silicide region;

FIG. 1b represents a graph which schematically illustrates a dopant profile in the depth direction of the conventional transistor shown in FIG. 1a;

FIG. 1c schematically shows a cross-sectional view of the transistor of FIG. 1 after the formation of metal silicide regions according to a conventional technique;

FIGS. 2a-2b represent graphs for illustrating an exemplary dependency of the diffusivity of a refractory metal with respect to the penetration depth in the presence of an exemplary conventional dopant concentration (FIG. 2a) and an illustrative example of a dopant concentration according to illustrative embodiments of the present invention;

FIGS. 2c-2f schematically illustrate cross-sectional views of a transistor element during various manufacturing stages in accordance with illustrative embodiments of the present invention;

FIG. 3 schematically shows a cross-sectional view of a semiconductor device comprising two transistor elements with different target depths for forming metal silicide regions in accordance with illustrative embodiments of the present invention; and

FIG. 4 schematically shows a cross-sectional view of a transistor element during fabrication, wherein a dopant concentration is modified in accordance with illustrative embodiments of the present invention on the basis of epitaxial silicon deposition.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

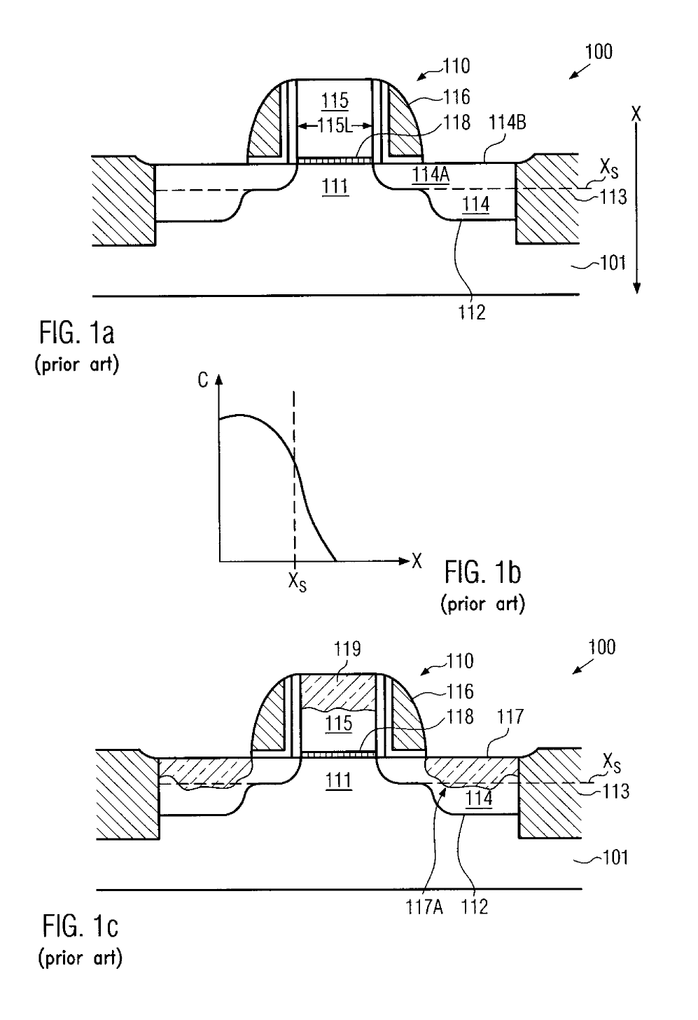

Generally, the present invention is based on the concept that the diffusivity of refractory metal within a doped semiconductor region may be influenced by the dopant profile within the semiconductor region. Thus, by appropriately adapting the dopant profile of drain and source regions of transistors formed on the basis of silicon, the kinematic behavior during a chemical reaction for forming metal silicide regions in the drain and source regions may be influenced to obtain more precisely defined interfaces between the metal silicide region and the semiconductor region, thereby reducing any deleterious effects that may be caused by metal silicide interface roughness, as is described with reference to FIG. 1c.

Without intending to restrict the present invention to the following explanation, it is believed that the diffusivity of refractory metal atoms within a substantially crystalline semiconductor region is significantly affected by the presence of dopants, in particular when the dopants and the refractory metal atoms may exhibit a similar diffusivity within the semi-conductor region under consideration. In this respect, diffusivity may be understood as an averaged random distance an atom may move within the semiconductor crystal at a specified temperature, for example, during the formation of a metal silicide in a crystalline silicon region where reaction kinetics significantly depend on the type of metal used and on the temperature at which the chemical reaction is initiated. In the presence of additional dopants in the silicon region, the reaction speed for forming metal silicide may, however, be significantly influenced by the additional dopants, since the diffusion of the dopants and of the refractory metal atoms may be based on substantially the same crystal-specific mechanisms, in particular when the refractory metal and the dopant material may have a similar diffusion behavior within silicon.

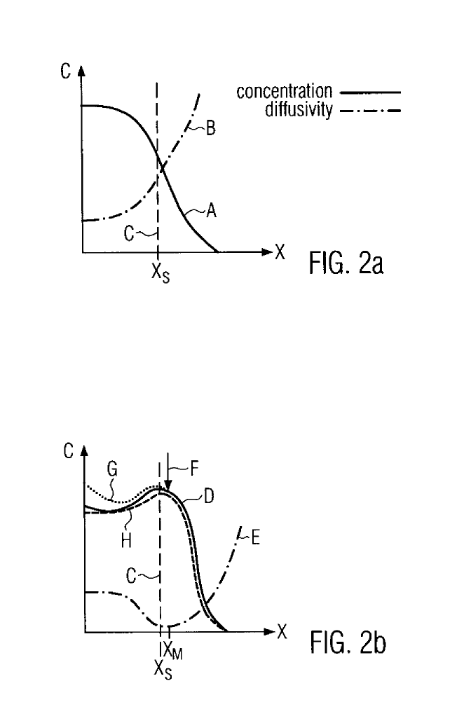

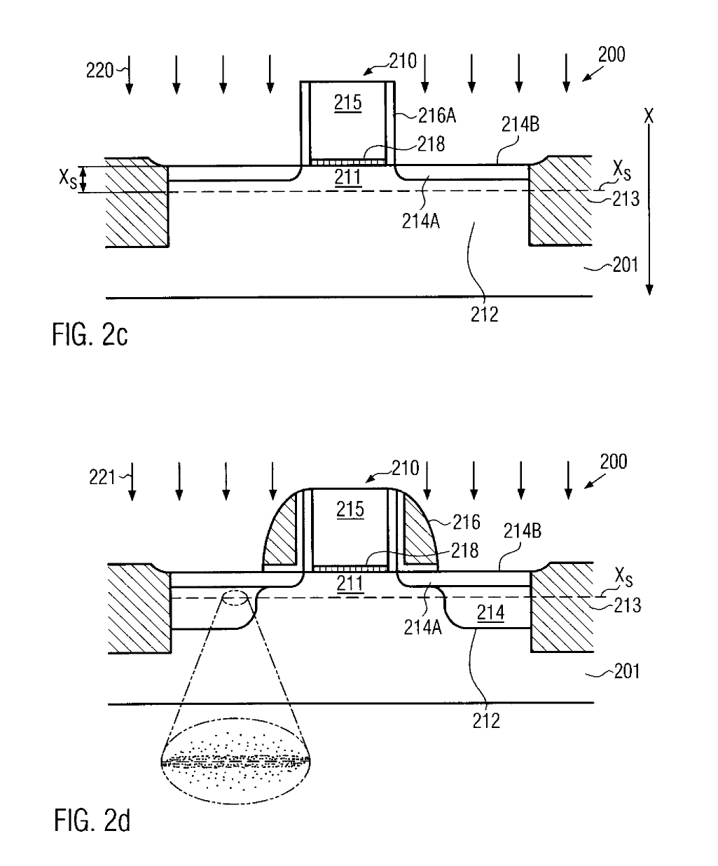

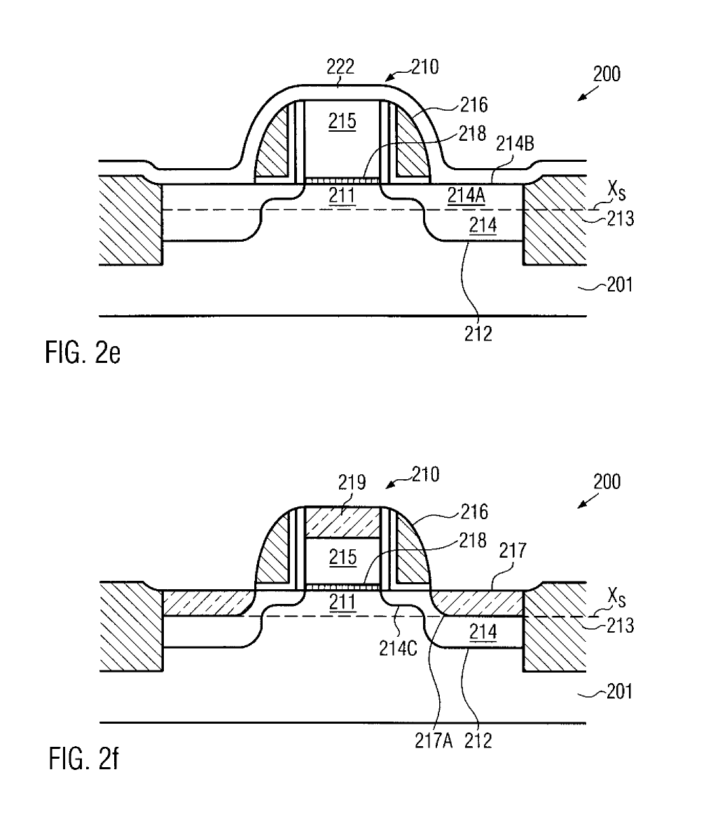

In FIG. 2a, the situation with respect to a dopant concentration and metal diffusivity in a silicon crystal is depicted in a very qualitative and simplified manner so as to more clearly illustrate the mechanism that is believed to have a significant effect on the process of forming metal silicide regions within a silicon-containing semiconductor crystal. However, it should be understood that, irrespective of the precise mechanism involved, the present invention is directed to various novel methods of producing a semiconductor device.

In FIG. 2a, curve A may qualitatively represent a typical conventional dopant concentration with respect to a depth direction, indicated as x and plotted as the horizontal axis. As is evident from FIG. 2a, the dopant concentration at a zero depth, i.e., the surface of a drain or source region, is moderately high, such as 10¹⁹ dopant atoms per cubic centimeter, which may drop significantly with increasing depth, so that a corresponding dopant concentration at a specified depth xₛ indicated by curve C, may be some orders of magnitude less than at depth 0, e.g., 10¹⁴-10¹⁵. Hereby, the depth xₛ may indicate a target depth for an interface between metal silicide and silicon of the drain or source region.

Curve B in FIG. 2a may qualitatively represent a corresponding diffusivity of a refractory metal within silicon for any given process conditions during a silicidation process. For example, curve B may schematically represent the diffusion speed of nickel for a specified process temperature during the formation of a nickel silicide region in a highly doped source or drain region. Due to the presence of a high amount of dopant atoms at the surface, i.e., depth 0, the initial diffusivity of the metal atoms may be moderately low, wherein it should be appreciated that certain fluctuations of the diffusion behavior of the metal atoms may be present at depth 0, which may be caused by any surface irregularities, and the like. Due to the moderately low diffusion speed, the chemical reaction will also progress at a moderate speed, wherein any initially present fluctuations of the reaction front are driven into the material, i.e., along the depth direction x, with substantially the same moderate reaction speed. However, with increasing depth, the concentration of the dopants may significantly drop, thereby resulting in a corresponding significant increase of the diffusivity of the metal atoms so that any fluctuations initially present in the reaction front may now be “amplified” due to the significantly increased reaction speed. Consequently, at the depth xₛ, a significant roughness of the corresponding metal silicide front may have built up due to this “amplification effect” caused by the drastically increased reaction speed. According to the present invention, a modified dopant concentration will be established to obtain an increased dopant concentration at or at least in the vicinity of the target depth xₛ compared to the dopant concentration as shown in FIG. 2a, thereby also modifying the reaction behavior during the silicidation process, which may result in a significantly reduced roughness of the metal silicide front.

FIG. 2b schematically shows a graph depicting a modified dopant concentration within a silicon-containing semiconductor region with respect to the depth direction x and a corresponding difference in diffusivity of a refractory metal that may be achieved due to the modified dopant concentration. Here, curve D represents the modified dopant concentration within a drain or source region, wherein an increased dopant concentration is centered around the target depth xₛ. It should be appreciated that the notion “increased” in this respect is to be understood that, at least at the target depth xₛ, an increase of the dopant concentration is present, when the target depth xₛ is approached from the left, i.e., with increasing depth so that at least within a certain neighborhood of xₛ, the dopant concentration increases with increasing depth. In other words, a local maximum of the dopant concentration with respect to the depth direction x is located at or in the vicinity of the target depth xₛ. Hereby, the notion “in the vicinity” or “near” is to be understood that a distance of the local maximum to the target depth xₛ is less than a distance of the local maximum to the location representing the depth 0, where a maximum dopant concentration may prevail in conventional devices. In some embodiments, the notion “near” or “in the vicinity” is meant to describe a depth of approximately 80-120% with the target depth being located at 100%. For example, in FIG. 2b, the actual local maximum may be located at a depth xₘ, indicated by arrow F, wherein this local maximum is located in the vicinity of the target depth xₛ since a distance of the local maximum to the target depth xₛ is significantly less compared to the distance of the target depth xₛ from the surface portion, i.e., the depth 0.

Curve E schematically represents the corresponding reaction speed with respect to a dopant concentration as represented for instance by curve D, wherein qualitatively a moderately low reaction speed is achieved, which even drops upon the respective increase of the dopant concentration, due to reduced diffusivity of the refractory metal atoms. Consequently, any initial fluctuations of the metal silicide front may not be substantially “amplified” and may even be reduced due to a “smoothing” effect of the reduced reaction speed. Thus, the metal silicide front may exhibit a reduced roughness and thus a more well-defined interface to the remaining silicon region at the target depth xₛ.

It should be appreciated that the dopant concentration and the diffusivity D, E are of illustrative nature only and other dopant profiles may be created in accordance with the present invention. For instance, curves G and H schematically show corresponding dopant profiles in the depth direction that may also be appropriate for forming a metal silicide interface in a more localized manner. It should be noted that the dopant concentrations shown in FIG. 2b may refer to a single dopant species having a specified conductivity type so that a corresponding profile is substantially determined by this single dopant species. For instance, an N-channel transistor may have heavily N-doped drain and source regions with only a negligible amount of counter dopants in the vicinity of the target depth xₛ, the effect of which on the dopant profiles may also be negligible, at least in the vicinity of the target depth xₛ. In other embodiments, however, the curves D, G, H may represent “accumulated” dopant concentration contemplating two or more different ion species, which may have the same or different conductivity types. For example, the high concentration at the target depth xₛ may be achieved by providing a certain amount of doping and by counter doping the area around the target depth xₛ so as to achieve a moderately low effective dopant concentration with respect to the electrical behavior, while still having an increased dopant concentration with respect to the actual number of dopant atoms per volume unit and thus with respect to the effect on the diffusivity of any metal used for the formation of a metal silicide region. Thus, unless otherwise recited in this description and in the appended claims, the notion “dopant concentration” is to be understood as the latter meaning.

With reference to FIG. 2c, further illustrative embodiments of the present invention will now be described in more detail. FIG. 2c schematically shows a semiconductor device 200 comprising a substrate 201, which may represent any appropriate substrate for the formation of silicon-based semiconductor elements. For instance, the substrate 201 may represent a bulk silicon substrate having formed on an upper portion thereof a crystalline silicon layer. In other cases, the substrate 201 may represent an SOI-type (silicon on insulator) substrate having formed above an insulating layer (not shown) a silicon-containing semiconductor layer. The semiconductor device 200 may further comprise a transistor element 210 including an isolation structure 213 formed within the substrate 201, i. e., within a silicon-containing semiconductor layer, so as to define an active region 212. Formed above the active region 212 is a gate electrode 215, which is separated from the active region 212 by a gate insulation layer 218. A channel region 211 is formed below the gate insulation layer 218 and laterally separates semiconductor regions in which deep drain and source regions are to be formed. Moreover, extension regions 214a are formed adjacent to the gate electrode 215, which may have formed on sidewalls thereof offset spacers 216a. The arrow x indicates a depth direction x, wherein the depth direction x is substantially orthogonal with respect to an initial surface of the substrate 201. That is, the depth direction x is well defined, even for any surface topology created above the substrate 201 during the manufacturing process of the device 200, as for instance the back side of the substrate 201 may be used to define the orthogonality of the depth direction x. With respect to the sign of the depth direction x as indicated by the arrow, it is to be understood that an increasing depth is considered as starting from a surface portion, such as the portion 214b with value 0 and directed into the substrate 201. Consequently, a target depth xₛ may be defined as the distance of the initial surface 214b and a desired position of an interface of a metal silicide region to be formed adjacent to the gate electrode 215. It should be appreciated that the “origin” of the depth direction x may be located above the surface 214b, when semiconductor devices 200 are considered, requiring the formation of selectively epitaxially grown source and drain regions, as will be described in more detail with reference to FIG. 4 later on.

A typical process flow for forming the semiconductor device 200 as shown in FIG. 2c may comprise the following processes. The transistor 210 to be formed in and on the active region 212 may represent a specified transistor type, such as an N-channel transistor or a P-channel transistor having specified transistor dimensions, such as a gate length, a gate width, a specified thickness of the gate insulation layer 218 and the like. Based on the device requirements of the transistor 210, the target depth xₛ is selected to obtain the desired decrease of the overall sheet resistivity of the surface portion 214b. The sheet resistivity and also the overall contact resistance of the drain and source regions to be formed in the transistor element 210 may significantly depend on the type of refractory metal used for forming the metal silicide region and the target depth xₛ. Since the overall performance of the transistor 210 may also significantly depend on the quality of the interface of the metal silicide region that is substantially formed at the target depth xₛ, the manufacturing processes for the device 200, in particular process recipes involved in forming the drain and source regions, are adapted on the basis of the target depth xₛ so as to obtain a modified dopant profile in the depth direction x, as is for instance described with reference to FIG. 2b. The formation of the device 200 may thus comprise any processes for forming the isolation structure 213 and the gate electrode 215 including the gate insulation layer 218 and the offset spacer 216a in accordance with well-established process techniques, as are also described with reference to FIG. 1a. Thereafter, an ion implantation process 220 may be performed to create a dopant concentration required for the formation of the extension regions 214a. Thereafter, in some embodiments, a rapid thermal anneal process may be performed to activate the dopants within the region 214a and also recrystallize implantation-induced damage. In other embodiments, the anneal procedure may be performed in a later stage after the formation of deep drain and source regions. Thereafter, appropriate spacer elements may be formed by well-established deposition and anisotropic etch techniques.

FIG. 2d schematically shows the semiconductor device 200 after the formation of spacer elements 216, which act as implantation masks during an ion implantation process 221 for forming deep drain and source regions 214. In one embodiment, the ion implantation 221 may be performed as a single implantation step, in which implantation parameters, such as implantation energy and dose are controlled on the basis of the target depth xₛ. Thus, the average penetration depth of the ion implantation 221 with respect to the dopant species used in this implantation process may be determined such that an increased dopant concentration is obtained in the vicinity of the target depth xₛ. A corresponding appropriate implantation energy for the dopant species under consideration may readily be determined on the basis of well-established simulation calculations. In other embodiments, the implantation process 221 may comprise two or more implantation steps so as to modify the vertical dopant profile in the manner as described above. In one embodiment, an additional implantation step may be performed which is designed to modify the preceding or subsequent implantation for the formation of the deep drain and source regions 214, thereby creating the desired increased dopant concentration at or in the vicinity of the target depth xₛ. In other embodiments, an additional implantation step may be performed on the basis of a different dopant species, which may have the same or a different conductivity type compared to the dopant species used for the preceding or subsequent implantation step for actually defining the drain and source regions 214. For example, a dopant species may be used for the formation of the deep drain and source regions 214 that exhibits a significantly different diffusivity compared to the refractory metal, which may be used subsequently in the formation of metal silicide regions in the drain and source regions 214. Thus, this dopant species may have a reduced effect on the diffusivity of the refractory metal so that the “amplification” effect may be somewhat less pronounced wherein, nevertheless, the introduction of a second dopant species having a more pronounced effect on the diffusivity of the refractory metal, i.e., having a similar diffusivity as the refractory metal, may even further enhance the smoothing effect of the increased dopant concentration at or in the vicinity of the target depth xₛ. In other embodiments, the second dopant species may differ in its conductivity type so as to act as a counter dopant, thereby reducing the “electrically effective” dopant concentration, while on the other hand increasing the actual dopant concentration, which acts as a reaction decelerating material.

It should be appreciated that in some embodiments the ion implantation 221, performed as a single step implantation or comprising two or more individual implantation steps on the basis of the same or different ion species, may be designed to obtain a high dopant concentration at or near the target depth xₛ, so that, for a given refractory metal or metals to be used in a subsequent silicidation process and given process conditions, the ion implantation 221 may be considered as a “barrier” implantation with respect to the subsequent silicide formation, since the reaction front is significantly “slowed down.” After the ion implantation process 221, the device 200 may be annealed to substantially activate the dopants incorporated during the implantation sequence 221 and possibly by the implantation 220 (FIG. 2c), and also to cure crystalline damage caused by the implantation 221 and 220.

FIG. 2e schematically shows the semiconductor device 200 in a further advanced manufacturing stage. Here, a layer of refractory metal 222 is conformally formed on the device 200. The layer 222 of refractory metal may be comprised of one or more metals, such as nickel, cobalt, titanium, platinum, tungsten and the like, wherein the layer 222 may be comprised of two or more sub-layers if different refractory metals are applied, or the layer 222 may be provided as a single layer formed from a single refractory metal or formed of a compound of two or more different refractory metals. The layer 222 may be formed on the basis of well-established deposition techniques, such as sputter deposition, chemical vapor deposition (CVD) and the like, wherein a thickness of the layer 222 is controlled on the basis of the target depth xₛ. Thus, the thickness of the layer 222 is sufficient to allow the formation of metal silicide down to the target depth xₛ. Corresponding data with respect to the silicon “consumption” during a silicidation process with one or more refractory metals of interest may be obtained on the basis of test runs, experience, and the like. Thereafter, the device 200 is subjected to a heat treatment under specified conditions, that is, a specified temperature and duration, so as to initiate the diffusion and thus the reaction of the refractory metal of the layer 222 with silicon in the regions 214 and in the gate electrode 215. In other examples, the formation of metal silicide in the gate electrode 215 may be decoupled from a corresponding process for forming metal silicide in the drain and source regions 214. For instance, a cap layer (not shown) may be provided on top of the gate electrode 215 so that the gate electrode 215 is protected during a subsequent silicidation process. Thereafter, the cap layer may be removed and a further layer of refractory metal may be deposited and a further chemical reaction may be initiated, in which substantially the gate electrode 215 is affected, while a reaction in the drain and source regions 214 may substantially be reduced due to previously formed metal silicide and due to the modified dopant concentration, which may significantly slow down a further penetration of the metal silicide front beyond the target depth xₛ. Thus, the gate electrode 215 may receive a different metal silicide, wherein the formation and thus the dimensions of the respective metal silicide may substantially be decoupled from the corresponding metal silicide regions in the drain and source regions 214.

In the following, it is assumed that the silicidation process is commonly performed for the gate electrode 215 and the regions 214. It should also be appreciated that depending on the material used, different process strategies may be required. For instance, cobalt may require a two-step heat treatment with an intermediate selective etch step for removing non-reacted cobalt so as to transform the cobalt silicide from a high ohmic phase into a low ohmic phase. For other materials, a single heat treatment may be appropriate, as is for instance the case for nickel, nickel platinum and the like. As is previously discussed with reference to FIG. 2b, during the chemical reaction, metal from the layer 222 diffuses into the region 214 wherein, due to the modified dopant profile in the depth direction x, a silicidation front of improved uniformity may form, thereby significantly reducing any roughness of an interface between metal silicide and semiconductor material.

FIG. 2f schematically shows the semiconductor device 200 after the completion of the above-described process sequence. Hence, the device 200 comprises a metal silicide region 219 formed in the gate electrode 215 and metal silicide regions 217 within the deep drain and source regions 214. Moreover, an interface 217a is substantially located at or in the vicinity of the target depth xₛ wherein the corresponding roughness is, at least in substantially horizontal portions, significantly reduced compared to prior art techniques. Consequently, disadvantageous effects, such as contact leakage currents and the like, may be reduced for a given transistor design, wherein the modification of the dopant profile in the depth direction may substantially not adversely affect the overall performance of the transistor 210, since the contact resistance of the transistor 210 is substantially determined by the conductivity of the metal silicide region 217 and not by the dopant concentration therein, whereas the location of the PN junction 214c may substantially remain unaffected by the modification of the dopant profile.

It should be appreciated that the modification of the dopant profile may be adapted in accordance with a desired target depth xₛ for a specific transistor type. For instance, as previously explained, P-type and N-type transistors usually commonly formed in CMOS devices may exhibit a different behavior with respect to the formation of a silicide region. Thus, a common target depth xₛ may be selected for both transistor types, wherein the respective modified dopant profiles may result in an increased uniformity of the formation of corresponding metal silicide regions. In other embodiments, different target depths xₛ or different transistor types may be considered appropriate and the implantation sequence for forming the modified dopant profile may be performed differently for the various different transistor types, as will be described next.

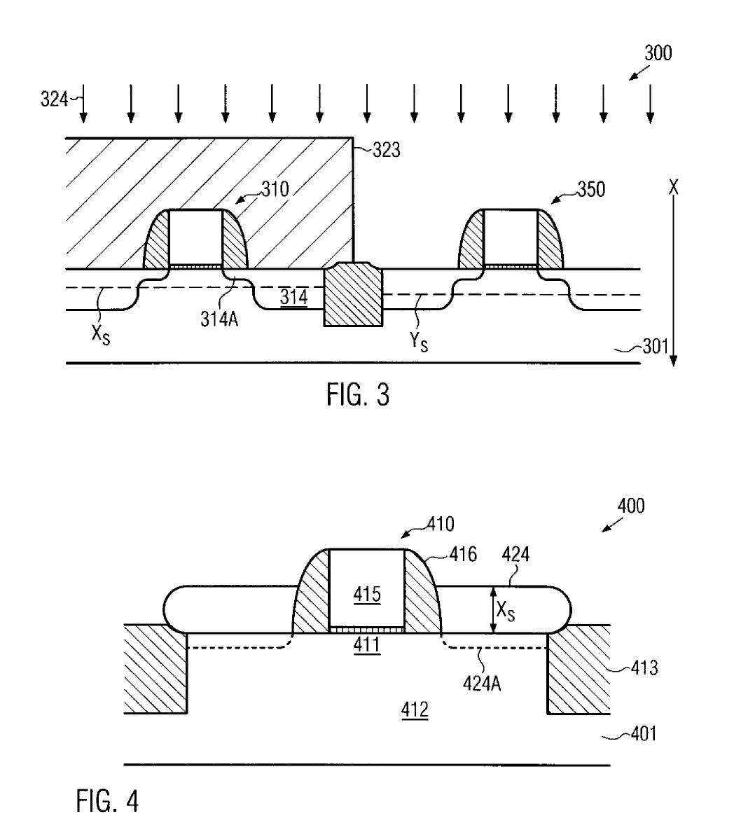

FIG. 3 schematically illustrates a semiconductor device 300 having formed therein two different types of transistors 310 and 350, which may require a metal silicide region having a different target depth xₛ and yₛ, respectively. In FIG. 3, the transistor 310 may comprise a deep drain and source region 314 and corresponding extension regions 314a, wherein a dopant profile along the depth direction may be modified as is previously discussed with reference to FIGS. 2b-2f. That is, the dopant concentration of the drain and source regions 314 is increased at the target depth xₛ. Moreover, the transistor 310 may be covered by a mask, such as a resist mask 323, to protect the transistor 310 during an implantation process 324 that is configured to form corresponding deep drain and source regions in the transistor 350 with a dopant profile having an increased dopant concentration at or in the vicinity of the target depth yₛ. Regarding the implantation process 324, the same criteria apply as previously described with reference to the implantation 221 (FIG. 2d). After the formation of deep drain and source regions in the transistor 350, corresponding anneal cycles may be performed and the further processing may be continued as is also described with reference to FIG. 2e. That is, a layer of refractory metal may be deposited with a thickness that is sufficient to consume silicon at least down to the target depth yₛ. Thus, a common silicidation process may be performed, while in particular the modified dopant profile in the transistor 310, having the smaller target depth xₛ, substantially maintains the silicide front at or in the vicinity of xₛ, while the silicide front in the second transistor 350 may progress down to the target depth yₛ. Consequently, a higher degree of process flexibility in the formation of metal silicide regions for different transistor types is provided without additional process complexity, since the formation of the resist mask 323 is a standard procedure in the conventional process flow, when different types of transistors are required.

FIG. 4 schematically shows a semiconductor device 400 having formed thereon a transistor element 410, in which at least a portion of dopants is introduced by deposition or diffusion. The transistor 410 comprises a gate electrode 415 having formed thereon spacer elements 416 adjacent to which are formed epitaxially grown silicon-containing semiconductor regions 424. Moreover, a target depth xₛ is shown, at which an interface of a metal silicide region has to be formed. It has to be appreciated that the target depth xₛ may also be located within an active region 412 that is formed within a substrate 401 prior to the formation of the regions 424. In principle, the transistor 410 may be formed in accordance with the process techniques previously described with reference to FIG. 1a and 2c-2f, wherein, prior to the formation of deep drain and source regions, the regions 424 may be formed by well-established selective epitaxial growth techniques, in which a specific dopant species may be added to the deposition atmosphere to provide the regions 424 as doped regions. Depending on the process parameters for controlling the deposition atmosphere of the selective epitaxial growth process, a desired vertical dopant profile may be adjusted. For example, since the deposition rate is well known for a given deposition recipe, the addition of the dopant precursor may be controlled on the basis of the target depth xₛ. For instance, a highly localized concentration peak may be created with a specified dopant species at the target depth xₛ. To this end, a corresponding burst of the dopant precursor may be generated in the deposition atmosphere of the selective epitaxial growth process, when the target depth xₛ is reached. If an extremely localized concentration peak is desired, the process parameters may be correspondingly adjusted in order to appropriately reduce the deposition rate, at least during the deposition of the material “in the vicinity” of the target depth xₛ. In other embodiments, a substantially uniform dopant concentration may be produced within the epitaxially grown regions 424 and the required modification of the dopant profile in the depth direction may be obtained by a specifically designed ion implantation process, as is also described with reference to FIG. 2d when referring to the ion implantation 221. In still other embodiments, a precise location of an increased dopant concentration, i. e., of the target depth xₛ, may have to be formed within the active region 412. In this case, the region 412 may be recessed adjacent to the spacer elements 416 by any appropriate technique, such as isotropic or anisotropic etching. In one illustrative embodiment, an oxidation process may be performed in a highly controllable manner and the silicon dioxide may be removed by well-established highly selective and well-controllable wet chemical etch techniques, thereby forming a recess 424a in a highly controllable fashion. Thereafter, the epitaxial growth process for forming the regions 424 may be performed in the same manner as described above, wherein now the target depth xₛ may be located within the recess 424a, thereby allowing a highly localized dopant concentration peak with a desired dopant species.

After the completion of the selective epitaxial growth process for forming the regions 424, optional further implantation processes may be performed to form deep drain and source regions having a vertical extension as required by device requirements. An anneal process may be performed to activate the dopants introduced by the optional ion implantation step. It should be appreciated that additional implantation processes for forming the deep drain and source regions may be omitted when the recesses 424a are formed and the dopant profile may substantially be completely established on the basis of controlling the dopant precursor concentration in the selective epitaxial deposition atmosphere. In this case, the anneal process may be omitted since the dopant atoms are typically placed at lattice sites. Thereafter, the spacer 416 may be removed by well-established highly selective etch techniques and then a corresponding implantation sequence may be performed to form extension regions adjacent to the gate electrode 415. Thereafter, further spacer elements, such as the spacers 416, may be formed and metal silicide regions may be formed in a similar way as is previously described with reference to FIG. 2f.

During this silicidation process, the highly localized increased dopant concentration at or in the vicinity of the target depth xₛ provides an enhanced “localization” of the metal silicide interface, thereby enhancing the overall characteristics of the transistor 410. Moreover, since a very high and very localized dopant concentration of an appropriate dopant species may be placed at or near the target depth xₛ, the “barrier” effect of the concentration peak may be adjusted to be extremely pronounced substantially without significantly affecting the overall “electric” dopant profile.

As a result, the present invention provides an enhanced technique for the formation of metal silicides having reduced non-uniformities at an interface to the remaining semiconductor region, thereby improving the performance of transistor elements. The improved metal silicide characteristics may be achieved by modifying the vertical dopant profile within the deep drain and source regions, wherein an increased dopant concentration is generated at or in the vicinity of a target depth for the metal silicide interface, which may form a “barrier” dopant concentration. The barrier concentration may significantly affect the diffusivity and thus the reaction speed during the metal silicide formation process. The barrier dopant concentration may be formed by a specifically designed implantation sequence, which may include one or more implantation steps, and/or by the introduction of dopants on the basis of an epitaxial deposition process. Irrespective of the way the increased dopant concentration is created, different dopant species having the same or different conductivity types may be used. In case different conductivity types are used, the dopant concentration affecting the metal diffusivity may be decoupled, at least to a certain degree, from the electrically effective dopant concentration, thereby providing enhanced flexibility in designing the barrier concentration substantially independently from the electric transistor performance.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
identifying a target depth of a metal silicide region to be formed in a silicon-containing semiconductor region formed above a substrate;
forming a dopant profile in said silicon-containing semiconductor region along a depth direction of said silicon-containing semiconductor region on the basis of said target depth so as to obtain a local maximum of a dopant concentration near said target depth; and
forming said metal silicide region on the basis of said target depth.

2. The method of claim 1, wherein forming said dopant profile comprises performing an ion implantation process, wherein an implantation dose and energy are controlled to substantially create said dopant profile.

3. The method of claim 2, wherein said ion implantation process comprises at least one first implantation step with a first dopant species of a first conductivity type.

4. The method of claim 3, wherein said dopant profile is substantially determined by said first dopant species.

5. The method of claim 3, wherein said ion implantation process comprises at least one second implantation step with a second dopant species other than said first dopant species, wherein said first and second dopant species substantially determine said local maximum.

6. The method of claim 1, wherein forming said dopant profile comprises introducing a dopant species by at least one of deposition and diffusion.

7. The method of claim 1, wherein said silicon-containing semiconductor region including said dopant profile represents at least one of a drain region and source region of a field effect transistor.

8. The method of claim 1, wherein forming said metal silicide region comprises depositing a layer of refractory metal above said silicon-containing semiconductor region and heat treating said substrate so as to initiate metal diffusion to form said metal silicide.

9. The method of claim 8, wherein at least one of a thickness of said layer of refractory metal, a temperature of said heat treatment and a duration of said heat treatment is controlled so as to stop a silicide growth substantially at said target depth.

10. A method, comprising:
identifying a first target depth for a metal silicide region for a drain and source region of a first specified transistor type to be formed on one or more substrates;
forming said drain and source regions of said first specified transistor type on one or more substrates with a dopant profile, with respect to a depth direction of said one or more substrates, on the basis of said first target depth so as to obtain, for increasing depth, an increasing dopant concentration when approaching said first target depth; and
forming said metal silicide region in said drain and source regions of the first specified transistor type on the basis of said first target depth.

11. The method of claim 10, wherein forming said drain and source regions comprises performing an ion implantation process, wherein implantation dose and energy are controlled to substantially create said dopant profile.

12. The method of claim 11, wherein said ion implantation process comprises at least one first implantation step with a first dopant species of a first conductivity type.

13. The method of claim 12, wherein said dopant profile is substantially determined by said first dopant species.

14. The method of claim 12, wherein said ion implantation process comprises at least one second implantation step with a second dopant species other than said first dopant species, wherein said first and second dopant species substantially determine said dopant profile.

15. The method of claim 10, wherein forming said drain and source regions comprises introducing a dopant species by at least one of deposition and diffusion.

16. The method of claim 10, wherein forming said metal silicide region comprises depositing a layer of refractory metal above a silicon-containing semiconductor region formed on said one or more substrates and heat treating said one or more substrates to initiate metal diffusion to form said metal silicide.

17. The method of claim 16, wherein at least one of a thickness of said layer of refractory metal, a temperature of said heat treatment and a duration of said heat treatment is controlled so as to stop the silicide growth substantially at said first target depth.

18. The method of claim 10, further comprising:
identifying a second target depth for a second metal silicide region to be formed in a drain and source region of a second specified transistor type to be formed on said one or more substrates;
forming said drain and source regions of said second specified transistor type with a second dopant profile, with respect to said depth direction of said one or more substrates, on the basis of said second target depth so as to obtain, for increasing depth, an increasing second dopant concentration when approaching said second target depth; and
forming said second metal silicide region in said drain and source regions of the second specified transistor type so as to stop a metal silicide growth substantially at said second target depth.
